(19) United States
(12) Patent Application Publication
(10) Pub. No.: US 2026/0352202 A1
(43) Pub. Date: Nov. 5, 2026

(54) DEGENERATION CIRCUITS AND DRIVERS USING THE SAME

(71) Applicant: Cypress Semiconductor Corporation, San Jose, CA (US)

(72) Inventors: Wasim HUSSAIN, Stockton, CA (US); Soon-Gil Jung, Santa Clara, CA (US); Nicholas Bodnaruk, Sunnyvale, CA (US); Murtuza Lilamwala, San Jose, CA (US)

(73) Assignee: Cypress Semiconductor Corporation, San Jose, CA (US)

(21) Appl. No.: 19/195,296

(22) Filed: Apr. 30, 2025

(51) Int. Cl. H03K 17/14; G06F 13/38

(52) U.S. Cl. CPC H03K 17/145; G06F 13/387

(57) ABSTRACT

A degeneration circuit includes a first transistor to provide a degeneration impedance. The degeneration circuit further includes a transimpedance amplifier coupled to the first transistor to bias the first transistor in ohmic mode and to provide process, voltage, or temperature variation tolerance for the degeneration circuit. The degeneration circuit further includes an input current source coupled to the transimpedance amplifier to set the degeneration impedance of the first transistor.

### TECHNICAL FIELD

Aspects and embodiments of the present disclosure relate to serialization/deserialization systems, and in particular to degeneration circuits and drivers using the same.

### BACKGROUND

Serialization/deserialization (SERDES) techniques enable devices to exchange data over serial data links. An example SERDES system may include a transmitter to convert parallel data into a serial data signal, a transmission channel to carry the serial data signal, and a receiver to convert the serial data signal back into parallel data. Examples of communications protocols that may use SERDES techniques include Universal Serial Bus (USB), Ethernet, Peripheral Component Interconnect Express (PCIe), and others.

### BRIEF DESCRIPTION OF DRAWINGS

Various embodiments in accordance with the present disclosure will be described with reference to the drawings, in which:

FIG. 1 is a block diagram of an example driver that includes a degeneration circuit, in accordance with an embodiment;

FIG. 2 is a block diagram of an example PVT-tolerant degeneration circuit, in accordance with an embodiment;

FIG. 3A is a block diagram of an example transimpedance amplifier for biasing a transistor of a degeneration circuit in a PVT-tolerant manner, in accordance with an embodiment;

FIG. 3B is a block diagram of an example transimpedance amplifier for biasing a transistor of a degeneration circuit in a PVT-tolerant manner, in accordance with an embodiment;

FIG. 4A is a block diagram of an example re-driver that includes a multi-stage driver, in accordance with an embodiment;

FIG. 4B is a block diagram of an example re-driver that includes a single-stage driver, in accordance with an embodiment;

FIG. 5A is a circuit diagram of an example single-stage variable-gain CML/line driver 500A which includes a degeneration circuit, in accordance with an embodiment;

FIG. 5B is a circuit diagram of an example single-stage variable-gain CML/line driver 500A which includes a degeneration circuit, in accordance with an embodiment; and

FIG. 6 illustrates an example embodiment of a re-driver integrated circuit (IC) controller, in accordance with the techniques described herein.

FIG. 7A illustrates an example embodiment of a re-driver IC controller for use in a notebook/desktop personal computer (PC) Universal Serial Bus (USB) application.

FIG. 7B illustrates an example embodiment of a re-driver IC controller for use in an active cable USB Type-C (USB-C) application.

### DETAILED DESCRIPTION

Aspects of the present disclosure relate to degeneration circuits and drivers using the same. SERDES systems can include a variety of driver subsystems for processing serial data streams. For example, a SERDES transmitter can include a continuous-time linear equalizer (CTLE), a variable-gain amplifier (VGA), a current-mode-logic (CML) line driver, and/or other types of drivers. These drivers can perform various functions such as providing linear or non-linear gain across a signal bandwidth or equalizing a signal. Some drivers can include degeneration circuits, such as degeneration resistor banks. Degeneration circuits can improve the linearity of driver gain, as well as provide programmable control of driver gain.

Drivers using degeneration circuits can face challenges related to linearity of degeneration circuits across process, voltage, and/or temperature (PVT) variations. For example, values of degeneration resistors can vary across PVT, which can prevent drivers from meeting target gain specifications across operating bandwidths. SERDES systems can face additional challenges related to power consumption of some driver subsystems that are divided into multiple driver stages. For example, a re-driver transmitter can include a two-stage subsystem that includes a VGA and a CML line driver. Such two-stage subsystems can increase power consumption of the re-driver.

Aspects of the present disclosure address the above challenges and other challenges by using degeneration circuits that include a transimpedance amplifier providing PVT tolerance. Further challenges with multistage drivers are addressed using single-stage drivers to reduce power consumption. The single-stage drivers can include the above degeneration circuits. These aspects are further described below.

In an embodiment, a system includes a degeneration circuit with a first transistor operating in ohmic mode to provide degeneration impedance (e.g., resistance and/or reactance). A transimpedance amplifier is coupled to the transistor to bias the first transistor in ohmic mode. The transimpedance amplifier can include a second transistor matched to the first transistor (e.g., having similar geometry) to mitigate PVT effects on the first transistor, thus providing PVT variation tolerance for the system. The transimpedance amplifier can be driven by an input current source (e.g., a programmable current source) to set the degeneration impedance of the first transistor. The degeneration circuits described herein can be used in various drivers, CTLE stages and other circuits benefiting from PVT tolerant degeneration impedance.

In an embodiment, a system includes a single-stage driver that combines functions often divided into stages in a multistage driver. For example, functions of a VGA and CML line driver in a linear re-driver can be combined into a single-stage driver (e.g., a variable-gain CML line driver) using a degeneration circuit to provide linearity and meet the target gain range. The single-stage drivers described herein can be used in various re-driver systems such as Physical Layers (PHYs) of communication systems (e.g., USB, Ethernet, etc.).

### Degeneration Circuits

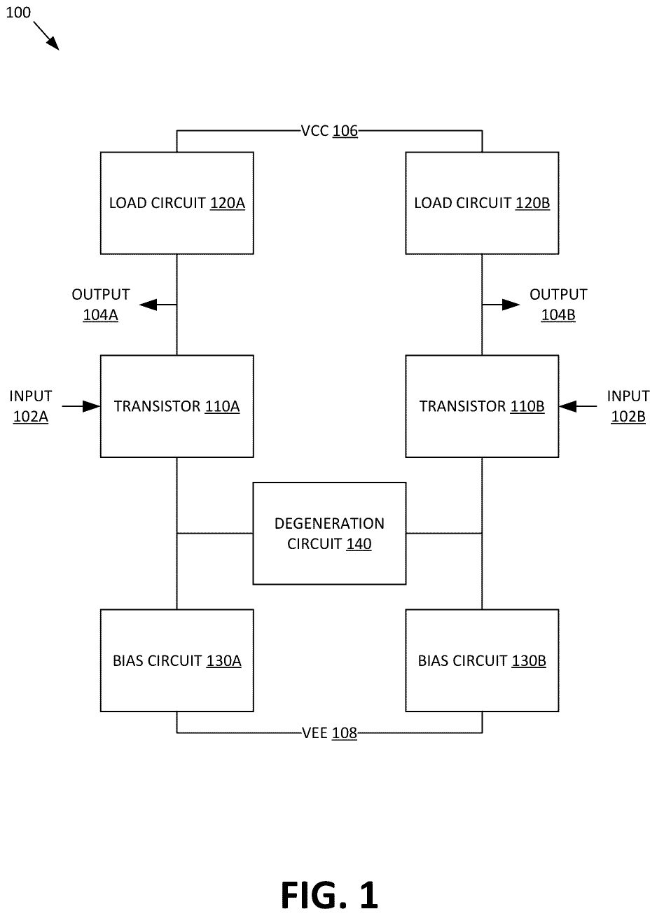

FIG. 1 is a block diagram of an example driver 100 that includes a degeneration circuit, in accordance with an embodiment. Driver 100 can be used in various systems, such as SERDES transmitters and/or receivers. For example, driver 100 can be a CTLE, a VGA, a CML line driver, or various other types of drivers. In various embodiments, the blocks depicted in FIG. 1 can correspond to subcircuits having one or more additional components. In various embodiments, driver 100 can include more, fewer, or different components than those depicted in FIG. 1. In an embodiment, driver 100 can be or can include a differential amplifier.

Driver 100 includes transistors 100A-B, which can be bipolar junction transistors (BJTs), field-effect transistors (FETS), insulated-gate bipolar transistors (IGBTs), or other types of transistors. Transistors 100A-B can receive input signals 102A-B, which can be a differential input signal. Driver 100 can be used with single-ended or differential signals ranging from, e.g., 0 Hz to, e.g., multiple GHz in various embodiments. Driver 100 further includes load circuits 120A-B coupled to respective transistors 110A-B and positive voltage rail VCC 106. Output signal nodes 104A-B are coupled to respective transistors 110A-B and load circuits 120A-B. Output signal nodes 104A-B can be coupled to a transmission channel (e.g., coaxial cable, twisted-pair cable, printed circuit board traces). Bias circuits 130A-B are coupled to respective transistors 110A-B and negative voltage rail VEE 108. In various embodiments, one of VCC 106 or VEE 108 can be a reference or ground rail.

Driver 100 further includes degeneration circuit 140 coupled to conduction terminals of transistors 110A-B (e.g., source or emitter terminals) and to bias circuits 130A-B. Degeneration circuit 140 can introduce negative feedback that provides various advantages to driver 100, such as improved linearity, increased input impedance, PVT tolerance, or similar. Degeneration circuit 140 can also provide improved control (e.g., programmable control) of driver 100's gain. Degeneration circuit 140 can be characterized by an impedance value, such as a resistance value. In various embodiments, degeneration circuit 140 can respond to direct current (DC) and/or alternating current (AC) signal components.

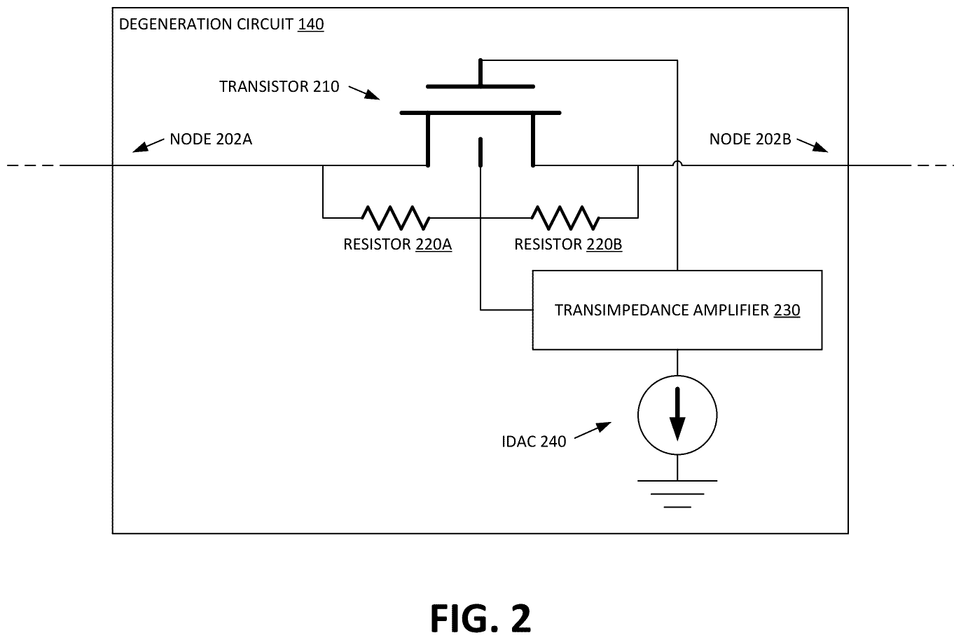

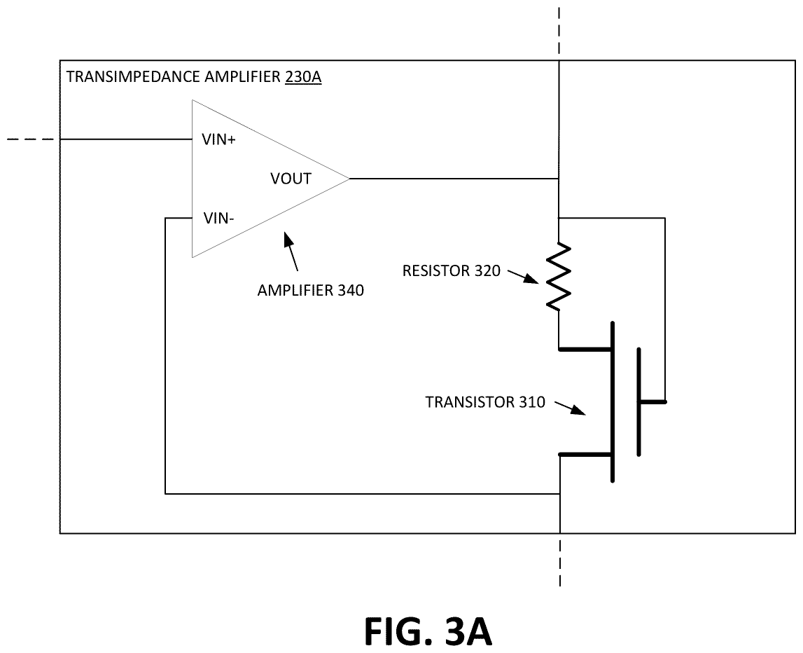

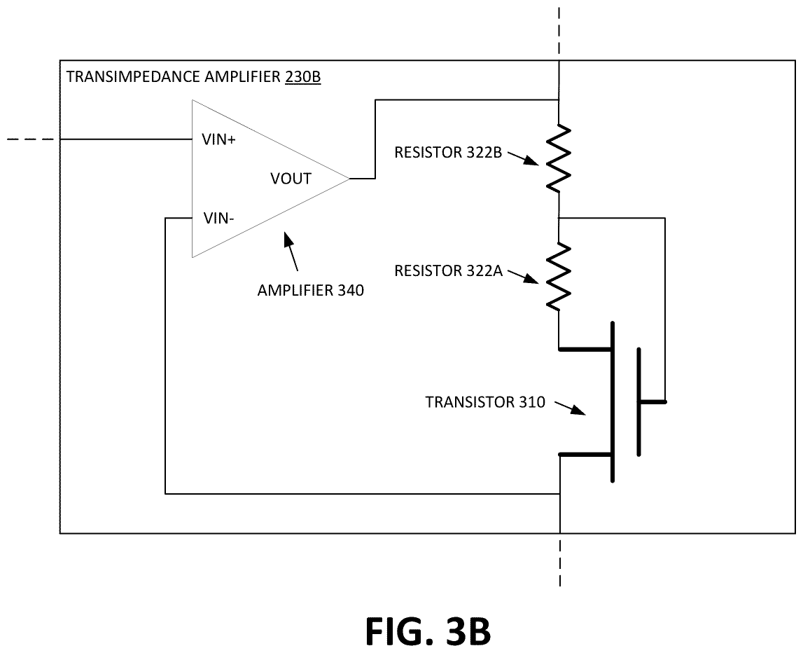

In an embodiment, degeneration circuit 140 can include one or more passive components, such as resistors, capacitors, and/or inductors, to provide a desired degeneration impedance. In an embodiment, degeneration circuit 140 can include one or more banks of passive components, which can be switched on or off to provide variable degeneration impedance and thus control the gain of driver 100. In an embodiment, degeneration circuit 140 can include one or more active components, such as a transistor operating in ohmic mode (also referred to as “triode mode” or “linear mode” in various embodiments), to provide a desired and/or variable degeneration impedance. As previously discussed, some embodiments of degeneration circuit 140 can be intolerant to PVT variations. Examples of PVT-tolerant degeneration circuits that include active components are further described with reference to FIGS. 2-3B.

FIG. 2 is a block diagram of an example PVT-tolerant degeneration circuit 140, in accordance with an embodiment. Degeneration circuit 140 can be used in driver 100 or in other circuits in various embodiments. In various embodiments, blocks depicted in FIG. 2 can correspond to subcircuits having one or more additional components. In various embodiments, degeneration circuit 140 can include more, fewer, or different components than those depicted in FIG. 2.

Degeneration circuit 140 includes transistor 210, which can be one of the various types of transistors discussed with reference to FIG. 1. For example, transistor 210 can be an N-channel metal-oxide-semiconductor (NMOS) FET or a P-channel MOSFET (PMOS). Transistor 210 includes two conduction terminals (also referred to as “drain” or “source” terminals in various embodiments), a gate terminal, and a bulk terminal. Transistor 210 can be biased in ohmic mode to provide degeneration impedance for a circuit external to degeneration circuit 140. The degeneration impedance can be provided across the conduction terminals between nodes 202A-B. Nodes 202A-B can be coupled respectively to transistors 110A-B and bias circuits 130A-B of FIG. 1.

In some degeneration circuits, a transistor such as transistor 210 can be susceptible to PVT variation, leading to undesirable changes in degeneration impedance. To mitigate this issue in degeneration circuit 140, transimpedance amplifier 230 can be used in combination with resistors 220A-B to bias transistor 210 in a PVT-tolerant manner. Resistors 220A-B, coupled to the bulk terminal and transimpedance amplifier 230, can be replicas of each other and can thus form a voltage divider pair setting the bulk terminal to the average potential of nodes 202A-B. This average potential is also provided as input reference to transimpedance amplifier 230. The resistance values of resistors 220A-B can be sufficiently large to minimize power consumption, e.g., R>>R_{S} (the degeneration resistance).

IDAC 240 is an input current source that can be used to set the degeneration impedance of transistor 210 via transimpedance amplifier 230. In an embodiment, IDAC 240 is a static current source that is set and/or tuned during fabrication. In an embodiment, IDAC 240 is a programmable current source that can change the degeneration impedance of transistor 210 (and thus the gain of an external driver circuit). For example, the current of IDAC 240 can be set by a digital-to-analog converter manipulated in firmware or software.

FIGS. 3A-B are block diagrams of example transimpedance amplifiers 230A-B for biasing a transistor of a degeneration circuit (e.g., transistor 210) in a PVT-tolerant manner, in accordance with an embodiment. Transimpedance amplifiers 230A-B can be used in degeneration circuit 140 or in other circuits in various embodiments. In various embodiments, blocks depicted in FIGS. 3A-B can correspond to subcircuits having one or more additional components. In various embodiments, transimpedance amplifiers 230A-B can include more, fewer, or different components than those depicted in FIG. 3A-3B.

Referring to FIG. 3A, transimpedance amplifier 230A includes transistor 310, which can be one of the various types of transistors discussed with reference to FIGS. 1-2. Transistor 310 can be matched to an external transistor (e.g., transistor 210) to mimic process variation behavior of the external transistor. For example, transistor 310 can be the same size as transistor 210 or can have the same width-length (W/L) ratio as transistor 210. In another example, various electrical characteristics or other characteristics of transistor 310 can be matched to transistor 210 during design, fabrication, or other lifecycle stage. In an embodiment, transistor 310 can be smaller than transistor 210 to reduce power consumption of transimpedance amplifier 230A.

Transistor 310 can be biased in ohmic mode by the combination of resistor 320, amplifier 340, and/or an external current source (e.g., IDAC 240 connected to the bottom conduction terminal of transistor 310). Amplifier 340 can be an operational amplifier, differential amplifier, or various other types of amplifiers. A VOUT output terminal of amplifier 340 can be coupled to resistor 320 and a gate terminal of transistor 310, as well as a gate terminal of an external degeneration transistor (e.g., transistor 210). A VIN+ input terminal of amplifier 340 can be coupled to a bulk terminal of an external degeneration transistor (e.g., transistor 210, also coupled to the average potential of nodes 202A-B). A VIN− input terminal of amplifier 340 can be coupled to a conduction terminal of transistor 310 and an external current source (e.g., IDAC 240).

The negative feedback loop formed by transistor 310, resistor 320, and amplifier 340 ensures that VIN+ and VIN− of amplifier 340 are of equal potential. As a result, transimpedance amplifier 230A ensures that the gate-source potential of transistor 310 is the same as the gate-source potential of transistor 210. Thus, transimpedance amplifier 230A can track the threshold potentials of transistors 210 and 310 across temperature variation and keep the resistance of transistors 210 and 310 relatively unchanged. Furthermore, as transimpedance amplifier 230A generates the gate-bulk potential for transistor 210 with reference to nodes 202A-B, the gate-bulk potential of transistor 210 is independent of VCC/VEE and any associated voltage variations.

In various embodiments, an optimum value of resistor 320 can depend on the threshold potential of transistors 210 and 310, bias currents of bias circuits 130A-B and/or IDAC 240, or other characteristics of driver circuit 100, degeneration circuit 140, and/or transimpedance amplifier 230A. A value for resistor 320 can be determined, for example, during the design and simulation stage of the development lifecycle. For example, Monte Carlo simulations can be used to characterize PVT variation tolerance and determine a value of resistor 320 that provides sufficient PVT tolerance. The resistance value of resistor 320 is thus predetermined to indicate PVT variation tolerance of the degeneration circuit.

In an embodiment, a supply voltage for transimpedance amplifier 230A can be different (e.g., higher) than the VCC/VEE supply for an external driver circuit (e.g., driver 100). This can provide advantages such as allowing additional flexibility in design and enabling driver gain control range to be maximized.

Referring to FIG. 3B and transimpedance amplifier 230B, an embodiment of a transimpedance amplifier can include an additional resistor 322B coupled to amplifier 340 and resistor 322A (or resistor 320 of FIG. 3A). Resistor 322B can provide an additional degree of freedom for circuit designers to achieve resistance matching of transistors 210 and 310.

### Single-Stage Drivers Using Degeneration Circuits

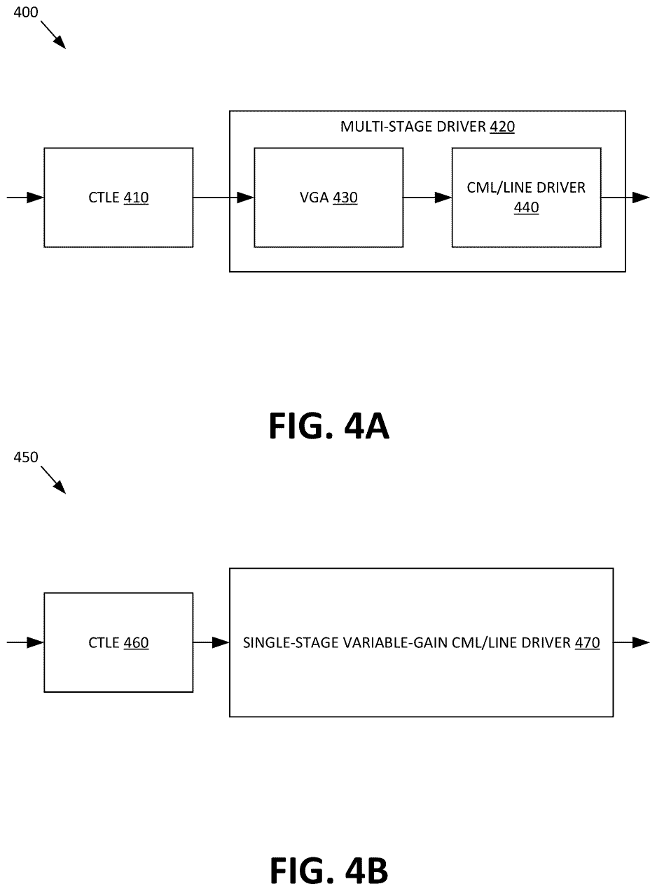

FIG. 4A is a block diagram of an example re-driver circuit 400 that includes a multi-stage driver, in accordance with an embodiment. Re-driver circuit 400 can be used in various systems, such as USB or Ethernet PHYs. In various embodiments, the blocks depicted in FIG. 4A can correspond to subcircuits having one or more additional components. In various embodiments, re-driver circuit 400 can include more, fewer, or different components than those depicted in FIG. 4A. In various embodiments, re-driver circuit 400 can be a linear re-driver, a limiting re-driver, or other type of re-driver.

Re-driver circuit 400 can include one or more components preceding or following multi-stage driver 420, such as CTLE 410 and/or one or more transmission channels. Multi-stage driver 420 can include multiple driver stages, such as VGA 430 and CML/line driver 440. For example, VGA 430 can be used to apply variable gain to a signal across an operating bandwidth, and CML/line driver 440 can be used to drive a load (e.g., a 50-Ohm load) with fixed gain. Each stage of multi-stage driver 420 can include additional or duplicative circuitry (e.g., bias circuits) that contribute to power consumption of re-driver circuit 400, and thus multi-stage driver 420 can be a source of excessive power consumption for re-driver circuit 400.

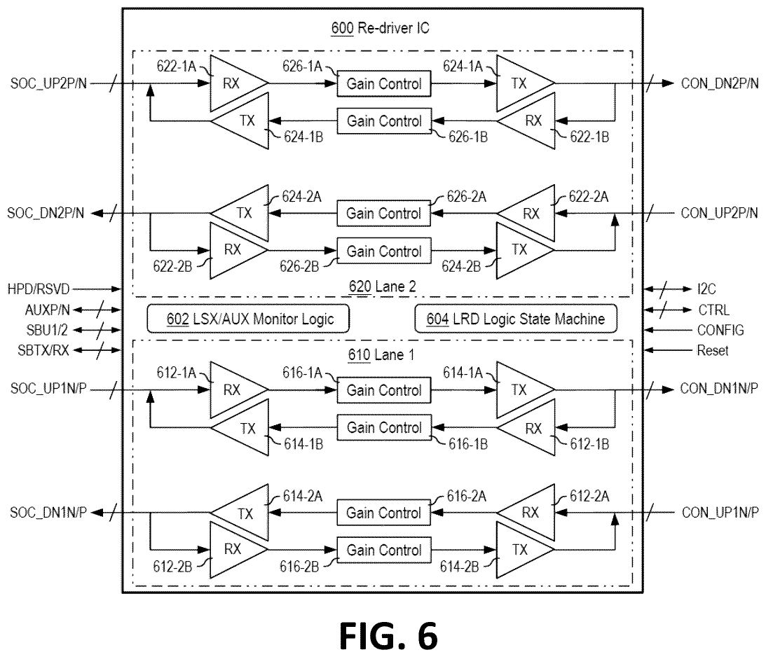

FIG. 4B is a block diagram of an example re-driver circuit 450 that includes a single-stage driver, in accordance with an embodiment. Re-driver circuit 450 can similarly be used in various systems, such as a USB PHY of a USB system (as described with reference to FIG. 6) or an Ethernet HPY of an Ethernet system. In various embodiments, the blocks depicted in FIG. 4B can correspond to subcircuits having one or more additional components. In various embodiments, re-driver circuit 450 can include more, fewer, or different components than those depicted in FIG. 4B. In various embodiments, re-driver circuit 450 can be a linear re-driver, a limiting re-driver, or other type of re-driver.

As with re-driver circuit 400, one or more components can precede or follow single-stage driver 470 (e.g., CTLE 460). Single-stage driver 470 can perform functions attributed to multiple stages in multi-stage driver 420. For example, single-stage driver 470 can be a single-stage variable-gain CML/line driver that combines the linear gain capabilities of a VGA with the load-driving capabilities of a CML/line driver. Shared circuitry can reduce power consumption of single-stage variable-gain CML/line driver 470 compared to multi-stage driver 420 and can thus contribute to a more power-efficient re-driver circuit 450.

To combine the functions of a VGA with a CML/line driver, a variable degeneration resistor can be added to the CML/line driver to meet the target gain range and linearize the gain. Thus, the CML/line driver can resemble driver 100 of FIG. 1. As previously described, various variable degeneration resistors can be used (e.g., resistor banks, transistors in ohmic mode), but some variable degeneration resistors can be intolerant to PVT variations. For example, a formulation of the single-stage driver gain in an embodiment is:

$$GAIN = \frac{{R}_{L}}{2 {r}_{e} + {R}_{S}} ;$$

where R_{L} is the load resistance, rₑ is the emitter resistance, and R_{S} is the degeneration resistance. These parameters depend on process- and temperature-dependent variables, such as transistor transconductance gₘ, transistor gate-source potential V_{gs}, and/or transistor threshold potential V_{T}(for transistor-based variable degeneration resistors). As a result, the gain of the single-stage driver can vary across PVT variations and can go out of a target range for the single-stage driver.

To mitigate PVT effects in single-stage drivers, a degeneration circuit such as those described with reference to FIGS. 1-3B can be used. A transistor operating in ohmic mode can be biased with a transimpedance amplifier that includes a matched transistor to mitigate PVT variations. The transimpedance amplifier can be driven with a variable current source to set the gain of the degeneration circuit.

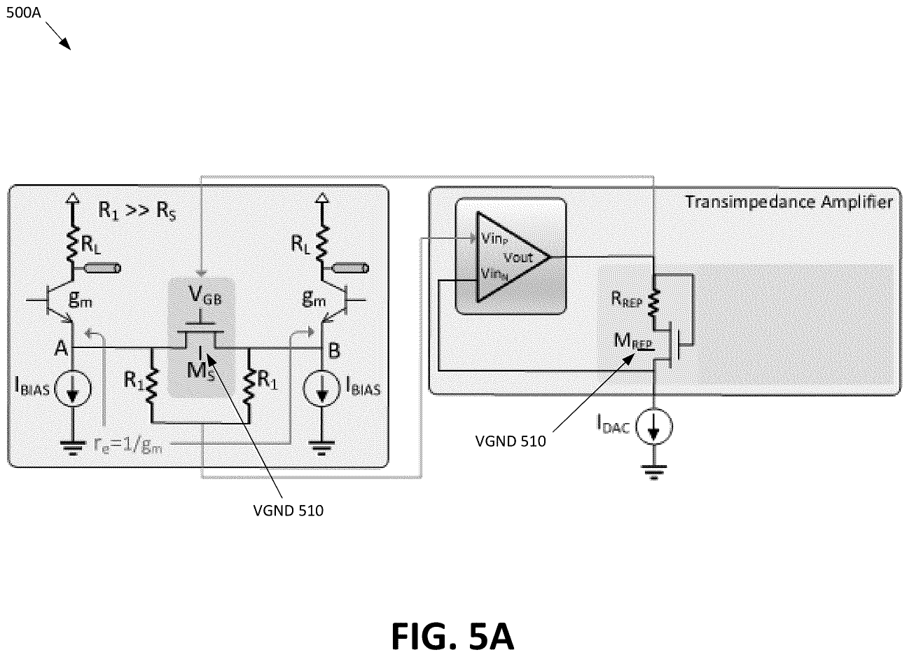

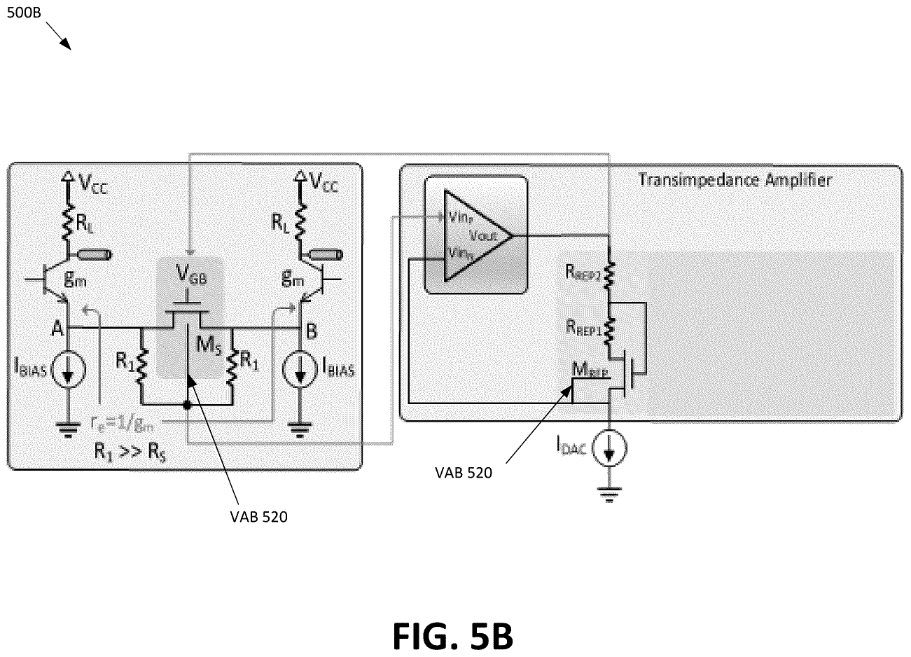

FIG. 5A is a circuit diagram of an example single-stage variable-gain CML/line driver 500A which includes a degeneration circuit as previously described, in accordance with an embodiment. The left side of FIG. 5A can correspond to the driver and degeneration circuitry described with reference to FIGS. 1-2, and the right side of FIG. 5A can correspond to the transimpedance amplifier circuitry described with reference to FIG. 3A.

FIG. 5B is a circuit diagram of an example single-stage variable-gain CML/line driver 500B which includes a degeneration circuit as previously described, in accordance with an embodiment. The left side of FIG. 5B can correspond to the driver and degeneration circuitry described with reference to FIGS. 1-2, and the right side of FIG. 5B can correspond to the transimpedance amplifier circuitry described with reference to FIG. 3B. The transimpedance amplifier depicted in FIG. 5B includes an extra resistor R_{REP2} that can be determined using techniques previously described (e.g., Monte Carlo and PVT simulation).

In an embodiment, as depicted in FIGS. 5A and 5B, the bulk terminals of a degeneration transistor (e.g., transistor 210) and a transimpedance amplifier transistor (e.g., transistor 310) can be connected to the same potential. In FIG. 5A, the bulk terminals are connected to a virtual ground reference (VGND 510). In FIG. 5B, the bulk terminals are connected to the average potential of nodes A and B (VAB 520), as determined by resistors R₁.

### Communication Systems

FIG. 6 illustrates an example embodiment of a re-driver integrated circuit (IC) controller 600 which, among other components, includes the degeneration circuits in accordance with the techniques described herein. Re-driver IC 600 may be configured for use in USB applications and non-USB applications. In USB applications, re-driver IC 600 may be controlled by a USB Power-Delivery (USB-PD) controller using an I²C interface. In non-USB applications, re-driver IC 600 (e.g., internal registers thereof) may be configured using dedicated general-purpose input/output (GPIO) pins for setting the equalization gain and for initial configuration.

In some USB applications, re-driver IC 600 is a USB4 compliant, 80 Gbps bi-directional two-lane linear re-driver configured to improve signal quality over long or noisy transmission lines and PC motherboards. In such embodiments, re-driver IC 600 is protocol agnostic and can operate on data transmitted over multiple protocols including USB, DisplayPort (DP), and PCI Express (PCIe) in various applications, including but not limited to notebook PCs, desktop PCs and active cables. Specific examples of such protocols include USB 3.x, USB 4.x, DisplayPort 2.x/1.4, Thunderbolt 5/4/3/2, and PCIe Gen 4/3/2. In some embodiments, re-driver IC 600 may also include a receiver adaptive equalization (AEQ) function that autonomously assesses input signal characteristics at channel start-up and selects optimal equalization, where the AEQ function can be enabled/disabled using control pins or through an I²C/SMBus interface.

For USB modes, in some embodiments re-driver IC 600 periodically conducts receiver detection on the transmission (TX) pairs upon channel startup. When it senses a termination, re-driver IC 600 activates Rx termination to indicate its readiness for signal transmission. For USB4/Thunderbolt3 modes, in some embodiments re-driver IC 600 monitors sideband traffic (e.g., on SBTX and SBRX lines) to optimize the performance and can decode Link Training (LT) transactions to determine link and power status. For USB3.2 operation, in some embodiments re-driver IC 600 provides an advanced power management capability that enables significant power saving under a low power slumber state and can detect LFPS (Low Frequency Periodic Signaling)/LBPM (LFPS Based PWM message) signaling and loss of signal (LOS), where these actions can be performed without host software intervention. For DisplayPort operation, in some embodiments re-driver IC 600 monitors the auxiliary (AUX) sideband traffic, decodes the AUX transactions to determine the number of active lanes and optimize the power usage, and may also support AUX-less Advanced Link Power Management (ALPM).

Referring to the example embodiment illustrated in FIG. 6, re-driver IC 600 includes listener/auxiliary (LSX/AUX) monitor logic 602, linear re-driver (LRD) logic state machine 604, various components comprising two data lanes (Lane-1 610 and Lane-2 620), and various data and control pins. LSX/AUX logic 602 comprises hardware logic configured to place re-driver IC 600 in the correct state in response to input and/or control signals. As used herein, “logic” refers to one or more hardware blocks having circuit(s) that include electronic components (e.g., such as transistors, diodes, resistors, capacitors, inductors, logic gates, and various circuits thereof) configured to process analog and/or digital signals and to perform one or more operations in response thereto. LRD logic state machine 604 comprises hardware logic configured to turn on re-driver IC 600, train the LRD circuits, and change the state of the re-driver IC.

Each of data lanes 610 and 620 includes two uni-directional channels, e.g., one up (UP) channel and one down (DN) channel. Each UP and DN channel includes a pair of differential transmit (TX) lines and a pair of differential receive (RX) lines.

For example, the UP channel (input pins SOC_UP1N/P, output pins CON_DN1N/P) of lane 610 includes RX equalizer circuit 612-1A, gain control circuit 616-1A, and TX circuit 614-1A, coupled in series. The UP channel of lane 610 also includes RX equalizer circuit 612-1B, gain control circuit 616-1B, and TX circuit 614-1B, coupled in series. The RX equalizer circuits 612-1A and 612-1B include CTLE and adaptive equalization (AEQ) circuits, which are configured in accordance with the techniques described herein. The TX circuits 614-1A and 614-1B are line drive circuits that are configured to match the impedance on the line being driven. The gain control circuits 616-1A and 616-1B include automatic gain control (AGC) circuits and are configured to compensate the loss of gain in the respective RX equalizer circuit. The DN channel (input pins SOC_DN1N/P, output pins CON_UP1N/P) of lane 610 includes RX equalizer circuit 612-2A, gain control circuit 616-2A, and TX circuit 614-2A, coupled in series. The DN channel of lane 610 also includes RX equalizer circuit 612-2B, gain control circuit 616-2B, and TX circuit 614-2B, coupled in series. The RX equalizer circuits 612-2A and 612-2B include CTLE and adaptive equalization (AEQ) circuits, which are configured in accordance with the techniques described herein. The TX circuits 614-2A and 614-2B are line drive circuits that are configured to match the impedance on the line being driven. The gain control circuits 616-2A and 616-2B include automatic gain control (AGC) circuits and are configured to compensate the loss of gain in the respective RX equalizer circuit.

Similarly, the UP channel (input pins SOC_UP2P/N, output pins CON_DN2P/N) of lane 620 includes RX equalizer circuit 622-1A, gain control circuit 626-1A, and TX circuit 624-1A, coupled in series. The UP channel of lane 620 also includes RX equalizer circuit 622-1B, gain control circuit 626-1B, and TX circuit 624-1B, coupled in series. The RX equalizer circuits 622-1A and 622-1B include CTLE and adaptive equalization (AEQ) circuits, which are configured in accordance with the techniques described herein. The TX circuits 624-1A and 624-1B are line drive circuits that are configured to match the impedance on the line being driven. The gain control circuits 626-1A and 626-1B include automatic gain control (AGC) circuits and are configured to compensate the loss of gain in the respective RX equalizer circuit. The DN channel (input pins SOC_DN2P/N, output pins CON_UP2P/N) of lane 620 includes RX equalizer circuit 622-2A, gain control circuit 626-2A, and TX circuit 624-2A, coupled in series. The DN channel of lane 620 also includes RX equalizer circuit 622-2B, gain control circuit 626-2B, and TX circuit 624-2B, coupled in series. The RX equalizer circuits 622-2A and 622-2B include CTLE and adaptive equalization (AEQ) circuits, which are configured in accordance with the techniques described herein. The TX circuits 624-2A and 624-2B are line drive circuits that are configured to match the impedance on the line being driven. The gain control circuits 626-2A and 626-2B include automatic gain control (AGC) circuits and are configured to compensate the loss of gain in the respective RX equalizer circuit.

Some of the data pins of re-driver IC 600 include: a HPD/RSVD pin (for DisplayPort Hot Plug Detect signal, reserved when DisplayPort is not used); AUXP/N pins (for DisplayPort AUX channel differential signals); SBU1/2 pins (for SBU1 and SBU2 signals used in USB communications); SBTX/RX pins (for SBTX and SBRX USB4 Thunderbolt sideband control signals). Some of the control pins of re-driver IC 600 include: I²C pins (for I²C data signals and control signals, e.g., clock and interrupts); CTRL pins (for AEQ and voltage level/linear range control signals); a CONFIG pin (for I²C/SMBus mode select signal), a Reset pin (for chip-select signal).

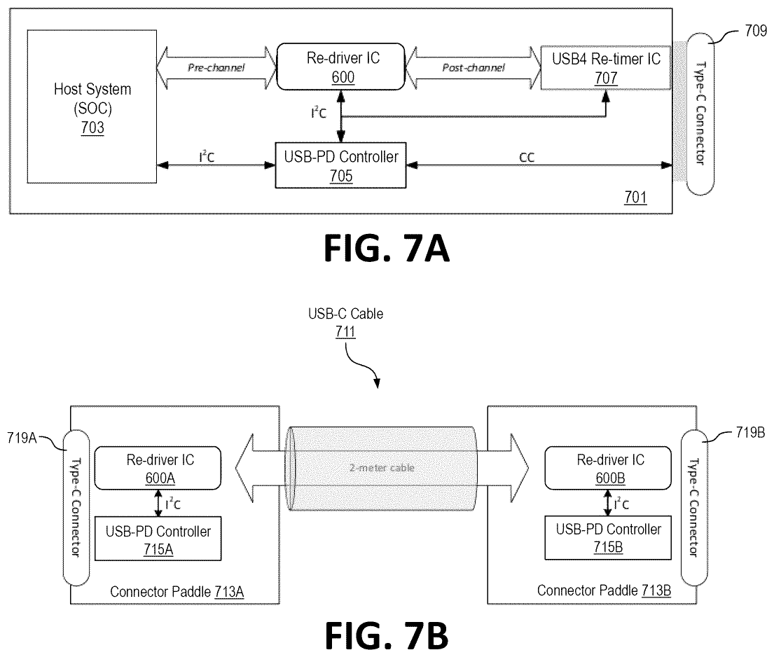

The re-driver IC 600 of FIG. 6 includes degeneration circuits and may be configured to operate in accordance with the techniques described herein in various USB applications. FIG. 7A illustrates an example embodiment of re-driver IC 600 in a notebook/desktop PC USB application. In notebook/desktop PC system 701, the upstream data facing port of re-driver IC 600 is coupled to receive data from host system (SOC) 703, and the downstream data facing port of the re-driver IC is coupled to transmit the data to USB4 re-timer IC 707. Re-timer IC 707 captures the data it receives using clock data recovery and then re-launches the data with a reference clock to a USB-C connector or to/over a USB-C cable. USB-PD controller 705 is coupled over I²C lines to control the operation of re-driver IC 600 and re-timer IC 707. FIG. 7B illustrates an example embodiment of re-driver IC 600 in an active cable USB-C application. Connector paddle 713A is disposed at one end of USB-C cable 711, and connector paddle 713B is disposed at the other end of USB-C cable 711. Within connector paddle 713A, USB-PD controller 715A is coupled over I²C lines to control the operation of re-driver IC 600A, which is coupled to receive/transmit data from/to USB-C connector 719A. At the other end of USB-C cable 711, within connector paddle 713B, USB-PD controller 715B is coupled over I²C lines to control the operation of re-driver IC 600B, which is coupled to receive/transmit data from/to USB-C connector 719B.

In the above description, numerous details are set forth. It will be apparent, however, to one of ordinary skill in the art having the benefit of this disclosure, that embodiments of the present disclosure may be practiced without these specific details. In some instances, well-known structures and devices are shown in block diagram form, rather than in detail, in order to avoid obscuring the description.

Some portions of the detailed description are presented in terms of algorithms and symbolic representations of operations on data bits within a computer memory. These algorithmic descriptions and representations are the means used by those skilled in the data processing arts to most effectively convey the substance of their work to others skilled in the art. An algorithm is here and generally, conceived to be a self-consistent sequence of steps leading to a desired result. The steps are those requiring physical manipulations of physical quantities. Usually, though not necessarily, these quantities take the form of electrical or magnetic signals capable of being stored, transferred, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. Unless specifically stated otherwise as apparent from the above discussion, it is appreciated that throughout the description, discussions utilizing terms such as “receiving,” “adjusting,” or the like, refer to the actions and processes of a computing system, or similar electronic computing device, that manipulates and transforms data represented as physical (e.g., electronic) quantities within the computing system's registers and memories into other data similarly represented as physical quantities within the computing system memories or registers or other such information storage, transmission or display devices.

The words “example” or “exemplary” are used herein to mean serving as an example, instance or illustration. Any aspect or design described herein as “example’ or “exemplary” is not necessarily to be construed as preferred or advantageous over other aspects or designs. Rather, the use of the words “example” or “exemplary” is intended to present concepts in a concrete fashion. As used in this application, the term “or” is intended to mean an inclusive “or” rather than an exclusive “or.” That is, unless specified otherwise, or clear from context, “X includes A or B” is intended to mean any of the natural inclusive permutations. That is, if X includes A; X includes B; or X includes both A and B, then “X includes A or B” is satisfied under any of the foregoing instances. In addition, the articles “a” and “an” as used in this application and the appended claims should generally be construed to mean “one or more” unless specified otherwise or clear from context to be directed to a singular form. Moreover, use of the term “an embodiment” or “one embodiment” or “some embodiments” throughout is not intended to mean the same embodiment or embodiments unless described as such.

The algorithms and displays presented herein are not inherently related to any particular device or other apparatus. Various systems (e.g., system-on-chip (SoC)) may be used with firmware in accordance with the teachings herein, or it may prove convenient to construct a more specialized device or apparatus to perform the required method steps. The required structure for a variety of these systems will appear from the description herein.

The above description sets forth numerous specific details, such as examples of specific systems, components, methods, and so forth, in order to provide a good understanding of several embodiments of the present disclosure. It will be apparent to one skilled in the art, however, that at least some embodiments of the present disclosure may be practiced without these specific details. In other instances, well-known components or methods are not described in detail or presented in simple block diagram format to avoid unnecessarily obscuring the present disclosure. Thus, the specific details set forth above are merely exemplary. Particular embodiments may vary from these exemplary details and still be contemplated to be within the scope of the present disclosure.

It is to be understood that the above description is intended to be illustrative and not restrictive. Many other embodiments will be apparent to those of skill in the art upon reading and understanding the above description. The scope of the disclosure should, therefore, be determined with reference to the appended claims, along with the full scope of equivalents to which such claims are entitled.

In the above description, for purposes of explanation, numerous specific details are set forth in order to provide a thorough understanding of the present disclosure. It will be evident, however, to one skilled in the art that the present disclosure may be practiced without these specific details. In other instances, well-known circuits, structures, and techniques are not shown in detail, but rather in a block diagram in order to avoid unnecessarily obscuring an understanding of this description.

Reference in the description to “one embodiment,” “an embodiment,” or “some embodiments” means that a particular feature, structure, or characteristic described in connection with the embodiment(s) is included in at least one embodiment of the disclosure. The phrase “in one embodiment” or “in some embodiments” located in various places in this description does not necessarily refer to the same embodiment(s).

What is claimed is:

1. A degeneration circuit comprising:
a first transistor to provide a degeneration impedance;
a transimpedance amplifier coupled to the first transistor to bias the first transistor in ohmic mode and to provide process, voltage, or temperature (PVT) variation tolerance for the degeneration circuit; and
an input current source coupled to the transimpedance amplifier to set the degeneration impedance of the first transistor.

2. The degeneration circuit of claim 1, wherein:
a first conduction terminal of the first transistor is coupled to a first resistor of a voltage divider pair;
a second conduction terminal of the first transistor is coupled to a second resistor of the voltage divider pair, wherein the second resistor is a replica of the first resistor;
a bulk terminal of the first transistor is coupled to the first resistor, the second resistor, and the transimpedance amplifier; and
a gate terminal of the first transistor is coupled to the transimpedance amplifier.

3. The degeneration circuit of claim 1, wherein the transimpedance amplifier comprises:
a second transistor biased in ohmic mode;
a first resistor coupled to a first conduction terminal and a gate terminal of the second transistor; and
an amplifier, wherein an input terminal of the amplifier is coupled to a second conduction terminal of the second transistor.

4. The degeneration circuit of claim 3, wherein the transimpedance amplifier further comprises:
a second resistor coupled to the first resistor and an output terminal of the amplifier.

5. The degeneration circuit of claim 3, wherein a resistance value of the first resistor is predetermined to indicate PVT variation tolerance of the degeneration circuit.

6. The degeneration circuit of claim 3, wherein a width-length (W/L) ratio of the second transistor is equal to a W/L ratio of the first transistor.

7. The degeneration circuit of claim 1, wherein the input current source is a programmable current source.

8. A driver circuit comprising:
a differential amplifier comprising a first transistor and a second transistor; and
a degeneration circuit coupled to respective conduction terminals of the first transistor and the second transistor, the degeneration circuit comprising:
a third transistor to provide a degeneration impedance;
a transimpedance amplifier coupled to the third transistor to bias the third transistor in ohmic mode and to provide process, voltage, or temperature (PVT) variation tolerance for the degeneration circuit; and
an input current source coupled to the transimpedance amplifier to set the degeneration impedance of the third transistor.

9. The driver circuit of claim 8, wherein the driver circuit is a continuous-time linear equalizer (CTLE).

10. The driver circuit of claim 8, wherein the driver circuit is a single-stage current mode logic (CML) line driver to provide linear gain.

11. The driver circuit of claim 8, wherein:
a first conduction terminal of the third transistor is coupled to a first resistor of a voltage divider pair;
a second conduction terminal of the third transistor is coupled to a second resistor of the voltage divider pair, wherein the second resistor is a replica of the first resistor;
a bulk terminal of the third transistor is coupled to the first resistor, the second resistor, and the transimpedance amplifier; and
a gate terminal of the third transistor is coupled to the transimpedance amplifier.

12. The driver circuit of claim 8, wherein the transimpedance amplifier comprises:
a fourth transistor biased in ohmic mode;
a first resistor coupled to a first conduction terminal and a gate terminal of the fourth transistor; and
an amplifier, wherein an input terminal of the amplifier is coupled to a second conduction terminal of the fourth transistor.

13. The driver circuit of claim 12, wherein the transimpedance amplifier further comprises:
a second resistor coupled to the first resistor and an output terminal of the amplifier.

14. The driver circuit of claim 12, wherein a resistance value of the first resistor is predetermined to indicate PVT variation tolerance of the driver circuit.

15. The driver circuit of claim 12, wherein a width-length (W/L) ratio of the fourth transistor is equal to a W/L ratio of the third transistor.

16. The driver circuit of claim 8, wherein the input current source is a programmable current source.

17. A Physical Layer (PHY) of a communication system, the PHY comprising a re-driver circuit, the re-driver circuit comprising:
a continuous-time linear equalizer (CTLE); and
a single-stage variable-gain current-mode-logic (CML) line driver to provide linear gain, the line driver comprising a degeneration circuit, the degeneration circuit comprising:
a first transistor to provide a degeneration impedance;
a transimpedance amplifier coupled to the first transistor to bias the first transistor in ohmic mode and to provide process, voltage, or temperature (PVT) variation tolerance for the degeneration circuit; and
an input current source coupled to the transimpedance amplifier to set the degeneration impedance of the first transistor.

18. The PHY of claim 17, wherein the PHY is a Universal Serial Bus (USB) PHY of a USB system.

19. The PHY of claim 17, wherein:
a first conduction terminal of the first transistor is coupled to a first resistor of a voltage divider pair;
a second conduction terminal of the first transistor is coupled to a second resistor of the voltage divider pair, wherein the second resistor is a replica of the first resistor;
a bulk terminal of the first transistor is coupled to the first resistor, the second resistor, and the transimpedance amplifier; and
a gate terminal of the first transistor is coupled to the transimpedance amplifier.

20. The PHY of claim 17, wherein the transimpedance amplifier comprises:
a second transistor biased in ohmic mode;
a first resistor coupled to a first conduction terminal and a gate terminal of the second transistor; and
an amplifier, wherein an input terminal of the amplifier is coupled to a second conduction terminal of the second transistor.

21. The PHY of claim 20, wherein the transimpedance amplifier further comprises:
a second resistor coupled to the first resistor and an output terminal of the amplifier.

22. The PHY of claim 20, wherein a resistance value of the first resistor is predetermined to indicate PVT variation tolerance of the line driver.

23. The PHY of claim 20, wherein a width-length (W/L) ratio of the second transistor is equal to a W/L ratio of the first transistor.

24. The PHY of claim 17, wherein the input current source is a programmable current source.
